(19) United States
(12) Patent Application Publication
(10) Pub. No.: US 2013/0111303 A1
(43) Pub. Date: May 2, 2013

(54) SINGLE ERROR CORRECTION & DEVICE FAILURE DETECTION FOR X8 SDRAM DEVICES IN BL8 MEMORY OPERATION

(71) Applicants: Karthikeyan Avudaiyappan, Sunnyvale, CA (US); Kalon Holdbrook, Palo Alto, CA (US)

(72) Inventors: Karthikeyan Avudaiyappan, Sunnyvale, CA (US); Kalon Holdbrook, Palo Alto, CA (US)

(73) Assignee: ORACLE INTERNATIONAL CORPORATION, Redwood Shores, CA (US)

(21) Appl. No.: 13/283,319

(22) Filed: Oct. 27, 2011

(51) Int. Cl. H03M 13/05; G06F 11/10

(52) U.S. Cl. 714/785; 714/E11.032

(57) ABSTRACT

A method of transmitting data with Enhanced Extended ECC by a transmitter includes obtaining a data polynomial, defining a generator polynomial, calculating a remainder polynomial by multiplying the data polynomial by x³² and dividing a result of the multiplication by the generator polynomial, calculating a final code polynomial by concatenating the remainder polynomial with the data polynomial, transmitting from the transmitter to a receiver a transmitted final code polynomial, receiving, at the receiver, a received final code polynomial that corresponds to the transmitted final code polynomial, and calculating, at the receiver, a syndrome of the received final code polynomial by dividing the received final code polynomial by the generator polynomial and XOR'ing a remainder of the division with the received remainder polynomial.

### BACKGROUND OF INVENTION

A server computing system includes one or more processors that each includes one or more processor cores. The system includes a memory controller that interfaces with one or more ranks of Synchronous Dynamic Random Accessible Memory (“SDRAM”). Each rank of SDRAM memory is comprised of a plurality of SDRAM devices that, together as a rank, provide access to a fixed number of bits at a time. For example, a conventional non-Error Correcting Code (“ECC”) rank of SDRAM memory may include eight x8 SDRAM devices, where each x8 SDRAM device may access 8 bits, so that the entire rank provides access to 64 bits at a time. Similarly, a conventional ECC rank of SDRAM memory may include nine x8 SDRAM devices, where each x8 SDRAM device may access 8 bits, so that the entire rank provides access to 72 bits at time, 64 of which are data bits and 8 of which are ECC related bits. From a power perspective, the use of x8 SDRAM devices is preferable to the use of x4 SDRAM devices.

Each processor core, through an integrated or external memory controller, interacts with a rank of SDRAM in units of cache-line-size that corresponds to the line size of the processor's cache. The cache line size typically corresponds to the line size of an L2 cache, typically 64 bytes. As a result, a number of memory accesses are required to produce the equivalent of a cache line. For example, in a non-ECC case, eight separate accesses of 64 bits are required to produce the 64-byte cache line. Similarly, in an ECC case, eight separate accesses of 72 bits are required to produce the 64-byte cache line and the 8-byte ECC data.

SDRAM supports bursting modes in which a rank of memory will perform a consecutive number of 64-bit or 72-bit accesses based on a single read or write command from the memory controller. SDRAM is typically configured to operate in a burst length of 4 (“BL4”) mode of operation or in a burst length of 8 (“BL8”) mode of operation. From a power and performance perspective, the BL8 mode of operation is preferable to the BL4 mode of operation.

### SUMMARY OF INVENTION

According to one aspect of one or more embodiments of the present invention, a method of transmitting data with Enhanced Extended ECC by a transmitter includes obtaining a data polynomial, defining a generator polynomial, calculating a remainder polynomial by multiplying the data polynomial by x³² and dividing a result of the multiplication by the generator polynomial, calculating a final code polynomial by concatenating the remainder polynomial with the data polynomial, transmitting from the transmitter to a receiver a transmitted final code polynomial, receiving, at the receiver, a received final code polynomial that corresponds to the transmitted final code polynomial, and calculating, at the receiver, a syndrome of the received final code polynomial by dividing the received final code polynomial by the generator polynomial and XOR'ing a remainder of the division with the received remainder polynomial.

According to one aspect of one or more embodiments of the present invention, a processor includes a substrate and a die disposed on the substrate. The die includes a plurality of processing cores and a memory controller. The memory controller, as a transmitter, performs a method of transmitting data with Enhanced Extended ECC that includes obtaining a data polynomial, defining a generator polynomial, calculating a remainder polynomial by multiplying the data polynomial by x³² and dividing a result of the multiplication by the generator polynomial, calculating a final code polynomial by concatenating the remainder polynomial with the data polynomial, and transmitting from the transmitter to a receiver a transmitted final code polynomial. The memory controller, as a receiver, performs the following: receiving a received final code polynomial that corresponds to a transmitted final code polynomial and calculating a syndrome of the received final code polynomial by dividing the received final code polynomial by the generator polynomial and XOR'ing a remainder of the division with the received remainder polynomial.

According to one aspect of one or more embodiments of the present invention, a system includes an input device, an output device, a mechanical chassis, a printed circuit board, a rank of system memory, and a processor. The processor includes a substrate and a die disposed on the substrate. The die includes a plurality of processing cores and a memory controller. The memory controller acts as a transmitter to and a receiver from the rank of system memory. The rank of system memory acts a transmitter to and a receiver from the memory controller. The memory controller, as the transmitter, and the rank of system memory, as the transmitter, perform a method of transmitting data with Enhanced Extended ECC that includes obtaining a data polynomial, defining a generator polynomial, calculating a remainder polynomial by multiplying the data polynomial by x³² and dividing a result of the multiplication by the generator polynomial, calculating a final code polynomial by concatenating the remainder polynomial with the data polynomial, and transmitting from the transmitter to a receiver a transmitted final code polynomial. The memory controller, as the receiver, and the rank of system memory, as the receiver, perform the following: receiving a received final code polynomial that corresponds to the transmitted final code polynomial, and calculating a syndrome of the received final code polynomial by dividing the received final code polynomial by the generator polynomial and XOR'ing the remainder of the division with the received remainder polynomial.

### BRIEF DESCRIPTION OF DRAWINGS

FIG. 1 shows a computing system in accordance with one or more embodiments of the present invention.

FIG. 2 shows a printed circuit board of the computing system in accordance with one or more embodiments of the present invention.

FIG. 3 shows a processor of the computing system in accordance with one or more embodiments of the present invention.

FIG. 4 shows a method of generating Enhanced Extended ECC in accordance with one or more embodiments of the present invention.

### DETAILED DESCRIPTION

Specific embodiments of the present invention will now be described in detail with reference to the accompanying figures. Like elements in the various figures are denoted by like reference numerals for consistency. Further, in the following detailed description of embodiments of the present invention, numerous specific details are set forth in order to provide a more thorough understanding of the present invention. In other instances, well-known features have not been described in detail to avoid obscuring the description of embodiments of the present invention.

FIG. 1 shows a computing system in accordance with one or more embodiments of the present invention. A computing system 100 includes an input device 110, an output device 120, and a mechanical chassis 130. The mechanical chassis 130 includes one or more printed circuit boards (“PCB”), a network device, and a storage device (not shown). In one or more embodiments of the present invention, the computing system 100 is a server, a workstation, a desktop computer, or a mobile computer. One of ordinary skill in the art will recognize the computing system could be any processor-based device.

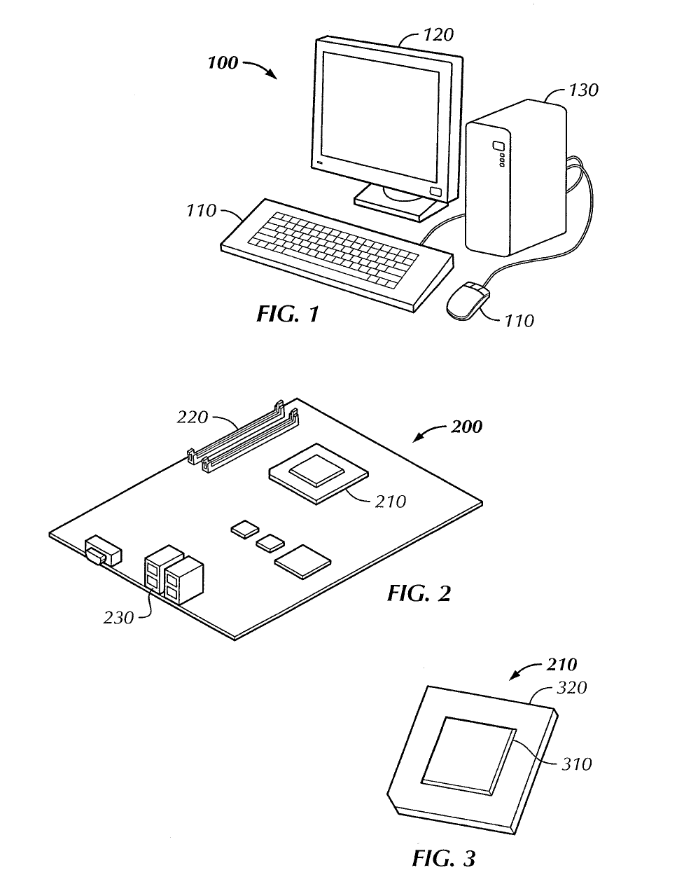

FIG. 2 shows a printed circuit board of the computing system in accordance with one or more embodiments of the present invention. PCB 200 includes one or more processors 210, a system memory 220, and a network device 230. PCB 200 includes conductors that serve as the interfaces between the various devices disposed on the PCB 200. One of ordinary skill in the art will recognize that the one or more processors 210, the system memory 220, and the network device 230 may be disposed on any combination of one or more PCBs 200 as part of the computing system 100.

FIG. 3 shows a processor of the computing system in accordance with one or more embodiments of the present invention. Each processor 210 includes one or more die 310 disposed on a substrate 320. Each die 310 includes one or more processing cores 330. Each processing core 330 includes one or more on-chip cache as part of a hierarchical organization of memory within the computing system 100. The on-chip cache may store instructions, data, or a combination of instructions and data. Each processor 210 includes an integrated memory controller that interacts with one or more ranks of system memory 220.

A processor 210 that consists of a single processing core is referred to a single-core processor. A single-core processor includes a private first level cache (“L1$”) and a private second level cache (“L2$”). In this instance, the L1$ and L2$ are private because they are for the exclusive use of the single-core processor. The caches are named in order of proximity to the core. In this instance, the cache closest to the core is designated the L1$. If the computing system 100 includes a plurality of single-core processors that share the system memory 220, additional hardware may be implemented within the computing system 100 to ensure coherency of the caches of each single-core processor and the system memory 220. One of ordinary skill in the art will recognize that the cache configuration of a single-core processor may vary in accordance with one or more embodiments of the present invention.

A processor 210 that consists of multiple processing cores is referred to as a multi-core processor. In a multi-core processor, each core includes a private L1$, a private L2$, and one or more third level caches (“L3$”). Each L3$ is shared by a subset or all of the processing cores that comprise the multi-core processor. In this instance, the L3$ is considered shared, because the L3$ is shared by a subset or all of the processing cores that comprise the multi-core processor. If the computing system 100 includes a plurality of multi-core processors that share the system memory 220, additional hardware may be implemented within the computing system 100 to ensure coherency of the caches of each processor and the system memory 220. One of ordinary skill in the art will recognize that the cache configuration of a multi-core processor may vary in accordance with one or more embodiments of the present invention.

In data transmission, there is a risk of undesired change in the data in-flight between the transmitting side and the receiving side. Because the interface between the memory controller and the SDRAM ranks of memory are bi-directional, each of the memory controller and the ranks of SDRAM memory serve as the transmitter and the receiver as required by a given transaction. The memory controller and the SDRAM ranks of memory are typically connected via conductors on one or more PCBs that may be susceptible to the in-flight corruption during transmission. Error detecting codes and error correcting codes detect and correct errors that occur as part of the transmission process to provide some measure of assurances that the received data is the transmitted data.

Conventional error detection codes and error correction codes can correct all errors from a single x4 SDRAM device or a single x8 SDRAM device in the BL4 mode of operation. Additionally, conventional error detection codes and error correction codes can correct all errors from a single x4 SDRAM device in the BL8 mode of operation. Oracle's Extended ECC recovery scheme can not detect or correct all errors from a single x8 SDRAM device in the BL8 mode of operation with nine x8 SDRAM devices per rank. Consequently, the Extended ECC recovery scheme, when used in the BL8 mode of operation with x8 SDRAM devices, can result in a large number of errors going undetected s a result of silent data corruption. Silent data corruption occurs, for example, when data with multiple errors matches a non-error data case. Because the errors go undetected, the errors can persist and will be treated as good data, resulting in further corruption. As a consequence, the reliable use of the BL8 mode of operation is limited to SDRAM ranks comprised of x4 SDRAM devices.

In one or more embodiments of the present invention, silent data corruption can be avoided by reliably detecting any number of errors from a single x8 SDRAM device in the BL8 mode of operation while also providing Single Error Correction (“SEC”). The detection of these errors prevents the errors from persisting and causing further corruption. By eliminating silent data corruption, a server system can reliably use x8 SDRAM devices in the BL8 mode of operation and realize a power and performance improvement over the use of x4 SDRAM devices in the BL4 mode of operation.

An ECC rank of memory has nine x8 SDRAM devices. Each x8 SDRAM device, upon read, delivers 32 data bits in two SDRAM cycles to form a check word size of 288 bits, i.e., 9 devices×32 bits=288 bits. Therefore, each x8 SDRAM device can give rise to 2³² unique errors. In a check word, there can be 9×2³² unique errors. In one or more embodiments of the present invention, all errors from a single x8 SDRAM device can be detected, one device at a time. In addition to being able to detect all errors from a single x8 DRAM device, i.e., Device Failure Detection (“DFD”), a single error located anywhere in the check word can be corrected, i.e., SEC. There are 288 unique single bit errors possible. As such, one or more embodiments of the present invention guarantees SEC and DFD for x8 SDRAM devices in the BL8 mode of operation.

Generally, Cyclic Redundancy Check (“CRC”) is an error detection code that detects errors in data. At a transmitting side, a CRC enabled device will generate a CRC code based on the data that is to be transmitted and the CRC code is transmitted with the data to the receiving side. At a receiving side, a CRC code is generated based on the received data. The transmitted CRC code is compared to the received CRC code. In the event the transmitted CRC code and the received CRC code are not the same, corrective action can be taken to ensure, to a limited extent, the accuracy of the received data before it is utilized. In each instance of generation, the CRC code is generated by performing a division calculation as part of the process of generating the CRC code. The division calculation includes a generator polynomial function as the divisor. The selection of the generator polynomial function impacts the extent to which the CRC code can ensure the accuracy of the received data.

The Enhanced Extended ECC method of the present invention employs a modified CRC(32) scheme. In CRC(32), redundant check bits are appended to the data bits to form the check word. The check bits and the data bits are represented by polynomial functions. If G(x) is the data polynomial function and P(x) is the generator polynomial function, then F(x) is the final code polynomial function that is transmitted. The final code polynomial function is F(x)=[R(x³²*G(x)/P(x)), G(x)], where R(x) represents the remainder of the modulo division, i.e., the product of x³² multiplied by G(x) and divided by P(x). This remainder is the check bits. These check bits are then appended to the original data polynomial, G(x), to form the final code polynomial, F(x). The received data is represented by the polynomial H(x). H(x)=F(x)+E(x), where E(x) is the error polynomial. If there is no error, i.e., E(x)=0, then H(x) equals F(x). The receiver divides H(x) by P(x). If the remainder of this division is {0}, then there is no error or there is no detectable error.

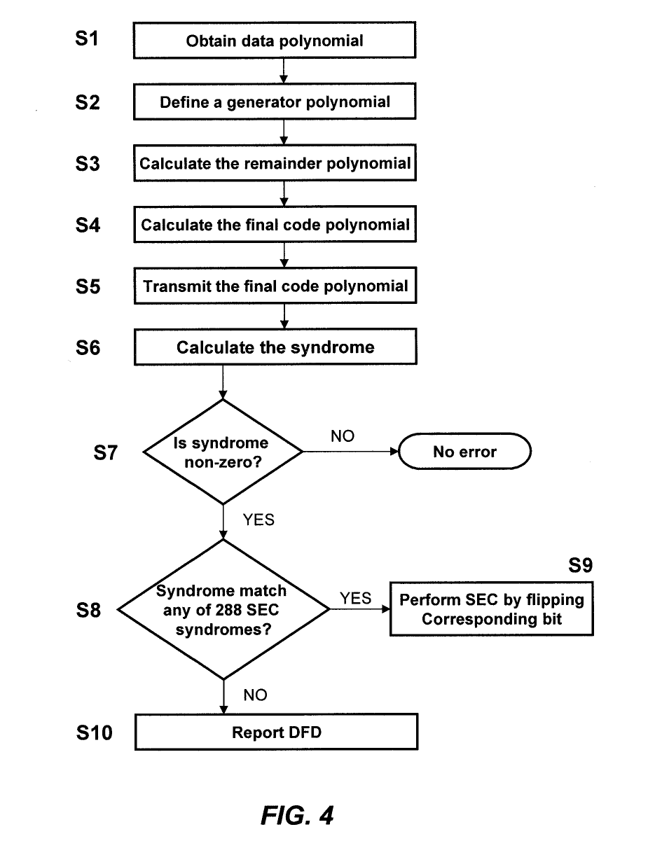

FIG. 4 shows a method of generating Enhanced Extended ECC in accordance with one or more embodiments of the present invention. One of ordinary skill in the art will recognize that the generating of Enhanced Extended ECC occurs at both the transmitter prior to transmission and at the receiver after reception in accordance with the Enhanced Extended ECC scheme disclosed herein. Additionally, one of ordinary skill in the art will recognize that the interface between the memory controller and the ranks of SDRAM memory are bi-directional, such that the memory controller and the ranks of SDRAM memory may each serve as the transmitter and the receiver as required in a given transaction. In step S1, a data polynomial is obtained. One of ordinary skill in the art will recognize that the data polynomial represents data and, accordingly, could vary in accordance with one or more embodiments of the present invention. For example, every term in the polynomial represents a data bit with value 1. For purposes of illustration only, the 8-bit data 0000 1110 can be represented by the polynomial 0x⁷+0x⁶+0x⁵+0x⁴+1x³+1x²+1x¹+0x⁰, which equals x³+x²+x. Thus, for the example, the data polynomial is defined as follows:

G(x)=x³+x²+x.

In step S2, a generator polynomial is defined. For purposes of illustration only, the generator polynomial is defined as follows:

P(x)=x³²+x²⁶+x²³+x²²+x¹⁶+x¹²+x¹¹+x¹⁰+x⁸+x⁷+x⁵+x⁴+x²+x+1

One of ordinary skill in the art will recognize that the generator polynomial could vary in accordance with one or more embodiments of the present invention. In step S3, the remainder of the modulo division is calculated. The remainder polynomial is defined as follows:

R(x)=x³²*G(x)/P(x).

For purposes of illustration only, given the above-noted G(x) and P(x), the remainder polynomial is calculated as follows:

R(x)=x³²*(x³+x²+x)/(x³²+x²⁶+x²³+x²²+x¹⁶+x¹²+x¹¹+x¹⁰+x⁸+x⁷+x⁵+x⁴+x²+x+1).

In step S4, the final polynomial code is calculated by concatenating R(x) and G(x) and is defined as follows:

F(x)=[R(x³²*G(x)/P(x)),G(x)].

For purposes of illustration only, given the above-noted G(x), P(x), and R(x), the final polynomial code is calculated as follows:

F(x)=x²⁹+x²⁸+x²⁷+x²²+x¹⁹x¹⁸+x¹⁷+x¹⁶+x¹⁵+x¹³+x¹²+x¹¹+x¹⁰+x⁸+x⁷+x⁵+x⁴+x³+x²+1,x³+x²+x

In step S5, the final polynomial code F(x) is transmitted from the transmitter to the receiver. As noted above, because the interface between the memory controller and the SDRAM ranks is bi-directional, when the memory controller is the transmitter the SDRAM rank is the receiver and when the SDRAM rank is the transmitter the memory controller is the receiver. In step S6, the receiver divides the received 288 bit check word by P(x). From this division, it computes the syndrome. The syndrome is the remainder of this division XOR'd with the received check bits. In step S7, a determination is made as to whether the syndrome is zero or non-zero. If the syndrome is {0}, no error or no detectable error is detected. This is because any single error will have a non-zero syndrome value and all single errors are detected. Furthermore, the non-zero syndrome value has the information necessary to determine the error bit and correct the error bit by matching one of the 288 SEC syndromes, i.e., SEC. In some cases of multiple errors, the syndrome may still be zero, and these are the still undetected errors. These can occur, for example, if two x8 devices have failed. In step S8, if the syndrome is non-zero, the receiver compares the syndrome against that of the 288 SEC syndromes. One of ordinary skill in the art will recognize that the 288 SEC syndromes depend on the polynomials chosen. If the syndrome matches any of the 288 SEC syndromes, in step S9, the corresponding data bit is flipped, i.e., SEC is performed. In step S10, if a particular x8 SDRAM device is giving rise to multiple errors, then there could be 2³² such errors. Because none of the 2³² errors' syndromes match that of the 288 SEC syndromes, a x8 SDRAM device failure is reliably detected, i.e., DFD is reported.

Advantages of one or more embodiments of the present invention may include one or more of the following.

In one or more embodiments of the present invention, the Enhanced Extended ECC allows for the reliable use of x8 SDRAM devices in the BL8 mode of operation.

In one or more embodiments of the present invention, the Enhanced Extended

ECC allows for the reliable use of x8 SDRAM devices in the BL8 mode of operation with only nine x8 SDRAM devices per rank.

In one or more embodiments of the present invention, the Enhanced Extended ECC avoids silent data corruption when x8 SDRAM devices are used in the BL8 mode of operation.

In one or more embodiments of the present invention, the Enhanced Extended ECC provides SEC and DFD for x8 SDRAM devices in the BL8 mode of operation.

In one or more embodiments of the present invention, the Enhanced Extended ECC allows for the use of x8 SDRAM devices in the BL8 mode of operation, thereby realizing a reduction in power consumption and a performance improvement over the use of x4 SDRAM devices.

In one or more embodiments of the present invention, the Enhanced Extended ECC allows for the use of x8 SDRAM devices in the BL8 mode of operation, thereby realizing a reduction in power consumption and a performance improvement over the use of x8 SDRAM devices in the BL4 mode of operation.

In one or more embodiments of the present invention, the Enhanced Extended ECC utilizes a generator polynomial that achieves 288 SEC syndromes that are unique and distinguishable from the 2³² DFD modes. Thus, SEC and DFD can be reliably implemented on x8 SDRAM devices in the BL8 mode of operation.

While the invention has been described with respect to a limited number of embodiments, those skilled in the art, having the benefit of this disclosure, will appreciate that other embodiments can be devised which do not depart from the scope of the invention as disclosed herein. Accordingly, the scope of the invention should be limited only by the attached claims.

What is claimed is:

1. A method of transmitting data with Enhanced Extended ECC by a transmitter comprising:
obtaining a data polynomial;
defining a generator polynomial;
calculating a remainder polynomial by multiplying the data polynomial by x³² and dividing a result of the multiplication by the generator polynomial;
calculating a final code polynomial by concatenating the remainder polynomial with the data polynomial;
transmitting from the transmitter to a receiver a transmitted final code polynomial;
receiving, at the receiver, a received final code polynomial that corresponds to the transmitted final code polynomial; and
calculating, at the receiver, a syndrome of the received final code polynomial by dividing the received final code polynomial by the generator polynomial and XOR'ing a remainder of the division with the received remainder polynomial.

2. The method of claim 1, further comprising:
determining, at the receiver, whether the syndrome is zero or non-zero;
if the syndrome is non-zero, at the receiver, comparing the syndrome to 288 SEC syndromes to determine whether a match exists; and
if the syndrome is non-zero and the syndrome matches one of the 288 SEC syndromes, at the receiver, performing SEC by flipping the corresponding data bit in the received final code polynomial.

3. The method of claim 2, further comprising:
if the syndrome is non-zero and does not match one of the 288 SEC syndromes, reporting a DFD has occurred.

4. The method of claim 1, wherein the generator polynomial is defined as {x³²+x²⁶+x²³+x²²+x¹⁶+x¹²+x¹¹+x¹⁰+x⁸+x⁷+x⁵+x⁴+x²+x+1}.

5. A processor comprising:
a substrate; and
a die disposed on the substrate,
wherein the die comprises:
a plurality of processing cores, and
a memory controller,
wherein the memory controller, as a transmitter, performs a method of transmitting data with Enhanced Extended ECC comprising:
obtaining a data polynomial,
defining a generator polynomial,
calculating a remainder polynomial by multiplying the data polynomial by x³² and dividing a result of the multiplication by the generator polynomial,
calculating a final code polynomial by concatenating the remainder polynomial with the data polynomial, and
transmitting from the transmitter to a receiver a transmitted final code polynomial, and
wherein the memory controller, as a receiver, performs the following:
receiving a received final code polynomial that corresponds to a transmitted final code polynomial, and
calculating a syndrome of the received final code polynomial by dividing the received final code polynomial by the generator polynomial and XOR'ing a remainder of the division with the received remainder polynomial.

6. The processor of claim 5, wherein the memory controller acting as the receiver further performs the following:
determining, at the receiver, whether the syndrome is zero or non-zero;
if the syndrome is non-zero, at the receiver, comparing the syndrome to 288 SEC syndromes to determine whether a match exists; and
if the syndrome is non-zero and the syndrome matches one of the 288 SEC syndromes, at the receiver, performing SEC by flipping the corresponding data bit in the received final code polynomial.

7. The processor of claim 6, wherein the memory controller acting as the receiver further performs the following:
if the syndrome is non-zero and does not match one of the 288 SEC syndromes, reporting a DFD has occurred.

8. The processor of claim 5, wherein the generator polynomial is defined as {x³²+x²⁶+x²³+x²²+x¹⁶+x¹²+x¹¹+x¹⁰+x⁸+x⁷+x⁵+x⁴+x²+x+1}.

9. A system comprising:
an input device;
an output device;
a mechanical chassis;
a printed circuit board;
a rank of system memory; and
a processor comprising:
a substrate; and
a die disposed on the substrate,
wherein the die comprises:
a plurality of processing cores, and
a memory controller,
wherein the memory controller acts as a transmitter to and a receiver from the rank of system memory,
wherein the rank of system memory acts a transmitter to and a receiver from the memory controller,
wherein the memory controller, as the transmitter, and the rank of system memory, as the transmitter, perform a method of transmitting data with Enhanced Extended ECC comprising:
obtaining a data polynomial,
defining a generator polynomial,
calculating a remainder polynomial by multiplying the data polynomial by x³² and dividing a result of the multiplication by the generator polynomial,
calculating a final code polynomial by concatenating the remainder polynomial with the data polynomial, and
transmitting from the transmitter to a receiver a transmitted final code polynomial, and
wherein the memory controller, as the receiver, and the rank of system memory, as the receiver, perform the following:
receiving a received final code polynomial that corresponds to the transmitted final code polynomial, and
calculating a syndrome of the received final code polynomial by dividing the received final code polynomial by the generator polynomial and XOR'ing the remainder of the division with the received remainder polynomial.

10. The system of claim 9, wherein the memory controller acting as the receiver further performs the following:
determining, at the receiver, whether the syndrome is zero or non-zero;
if the syndrome is non-zero, at the receiver, comparing the syndrome to 288 SEC syndromes to determine whether a match exists; and
if the syndrome is non-zero and the syndrome matches one of the 288 SEC syndromes, at the receiver, performing SEC by flipping the corresponding data bit in the received final code polynomial.

11. The system of claim 10, wherein the memory controller acting as the receiver further performs the following:
if the syndrome is non-zero and does not match one of the 288 SEC syndromes, reporting a DFD has occurred.

12. The system of claim 9, wherein the generator polynomial is defined as {x³²+x²⁶+x²³+x²²+x¹⁶+x¹²+x¹¹+x¹⁰+x⁸+x⁷+x⁵+x⁴+x²+x+1}.
